(19) United States
(12) Patent Application Publication
(10) Pub. No.: US 2025/0054897 A1
(43) Pub. Date: Feb. 13, 2025

(54) SEMICONDUCTOR MODULE

(71) Applicant: FUJI ELECTRIC CO., LTD., Kawasaki-shi (JP)

(72) Inventors: Mai SAITO, Kawasaki-shi (JP); Yoko NAKAMURA, Kawasaki-shi (JP); Tsubasa WATAKABE, Kawasaki-shi (JP); Akihiko IWAYA, Kawasaki-shi (JP)

(73) Assignee: FUJI ELECTRIC CO., LTD., Kawasaki-shi (JP)

(21) Appl. No.: 18/933,720

(22) Filed: Oct. 31, 2024

Related U.S. Application Data
(63) Continuation of application No. PCT/JP2023/036705, filed on Oct. 10, 2023.

(30) Foreign Application Priority Data
Nov. 4, 2022 (JP) 2022-177076

(51) Int. Cl. H01L 23/00; H01L 23/04; H01L 23/31; H01L 23/495; H05K 1/02

(52) U.S. Cl. CPC H01L 24/29; H01L 23/49562; H01L 24/32; H05K 1/0203; H01L 23/04; H01L 23/3121; H01L 2224/29017; H01L 2224/29018; H01L 2224/32225; H01L 2224/32245; H01L 2924/35

(57) ABSTRACT

A semiconductor module includes a stacked substrate in which a plurality of circuit boards are arranged on an upper surface of an insulating plate, a semiconductor element arranged on an upper surface of at least one of the circuit boards, and a metal wiring board arranged on an upper surface of the semiconductor element. The metal wiring board has a first bonding portion bonded to the upper surface of the semiconductor element via a bonding material. The first bonding portion includes a plate-shaped portion having an upper surface and a lower surface, and at least one groove is provided along an outer periphery of the first bonding portion on the upper surface of the plate-shaped portion.

### CROSS-REFERENCE TO RELATED APPLICATION

This is a continuation application of International Application PCT/JP2023/036705 filed on Oct. 10, 2023 which claims priority from a Japanese Patent Application No. 2022-177076 filed on Nov. 4, 2022, the contents of which are incorporated herein by reference.

### TECHNICAL FIELD

The present invention relates to a semiconductor module.

### BACKGROUND ART

A semiconductor module has a substrate, on which a semiconductor element such as an insulated gate bipolar transistor (IGBT), a power metal oxide semiconductor field effect transistor (MOSFET), or a free wheeling diode (FWD) is provided, and is used in an inverter device and the like.

In this type of semiconductor module, a semiconductor element is arranged on an insulating substrate (which may be referred to as a stacked substrate), and a metal wiring board for wiring (which may be referred to as a lead frame) is arranged on an upper surface electrode of the semiconductor element in, for example, Patent Literatures 1 to 3. The metal wiring board is formed into a predetermined shape by, for example, pressing a metal plate. One end of the metal wiring board is electrically bonded to the upper surface electrode with a bonding material such as solder.

In the semiconductor module, a sealing resin is filled in a case member, and an internal structure including the metal wiring board is covered with the sealing resin. In order to improve the adhesion strength of the sealing resin to the metal wiring board, Patent Literature 4 describes that a dovetail-shaped groove having a narrower open portion than the width of a bottom portion is formed in the metal wiring board, and Patent Literature 5 describes that a plurality of lattice-shaped grooves are formed in the metal wiring board.

Patent Literatures 6 to 9 describe that a plurality of dimples are formed on a surface of the metal wiring board and protrusions (bending portions, turnover portions, hook portions) are provided on inner walls of the dimples to improve the adhesion strength of the sealing resin. As a method of forming the dimples, holes are formed by the first pressing, and some of the holes are deformed to form the protrusions on the inner walls by performing the second pressing on peripheries of the holes.

### CITATION LIST

### Patent Literature

Patent Literature 1: JP 2018-088448 A
Patent Literature 2: JP 2016-139635 A
Patent Literature 3: JP 2015-176871 A
Patent Literature 4: JP 6-163773 A
Patent Literature 5: JP 2021-077718 A
Patent Literature 6: JP 7-273270 A
Patent Literature 7: JP 2005-191178 A
Patent Literature 8: JP 2017-005124 A
Patent Literature 9: JP 2007-258587 A

### SUMMARY OF INVENTION

### Technical Problem

In this type of semiconductor module, the power semiconductor element generates heat following a switching operation. In the structure in which the metal wiring board is solder-bonded to the surface of the power semiconductor element as described above, distortion may occur in the bonding portion due to a fluctuation of internal stress generated with temperature change. As a result, a decrease in the adhesion of the sealing resin to the bonding portion of the metal wiring board is assumed.

The present invention has been made in view of such a point, and an object of the present invention is to provide a semiconductor module capable of improving adhesion between a bonding portion of a metal wiring board and a sealing resin.

### Solution to Problem

A semiconductor module according to one aspect of the present invention includes: a stacked substrate in which a plurality of circuit boards are arranged on an upper surface of an insulating plate; a semiconductor element arranged on an upper surface of at least one of the circuit boards; and a metal wiring board arranged on an upper surface of the semiconductor element, in which the metal wiring board has a first bonding portion bonded to the upper surface of the semiconductor element via a bonding material, the first bonding portion includes a plate-shaped portion having an upper surface and a lower surface, and at least one groove is provided along an outer periphery of the first bonding portion on the upper surface of the plate-shaped portion.

### Advantageous Effects of Invention

According to the present invention, adhesion between a bonding portion of a metal wiring board and a sealing resin in a semiconductor module can be improved.

### BRIEF DESCRIPTION OF DRAWINGS

FIG. 1 is a schematic view of a semiconductor device according to a present embodiment as viewed from above.

FIG. 2 is a cross-sectional view of the semiconductor device illustrated in FIG. 1 taken along line A-A.

FIG. 3 is an enlarged view of a metal wiring board according to the present embodiment.

FIG. 4 is a plan view of the metal wiring board illustrated in FIG. 3 as viewed in a direction of arrow B.

FIG. 5 is an enlarged view of a portion C of the metal wiring board illustrated in FIG. 3.

FIG. 6 is a plan view illustrating a specific example of a semiconductor module to which the metal wiring board according to the present embodiment is applied.

FIG. 7 is an equivalent circuit diagram of the semiconductor device according to the present embodiment.

FIG. 8 is a plan view illustrating a first embodiment where a groove is provided on a surface of the metal wiring board.

FIG. 9 is a cross-sectional view taken along line D-D of FIG. 8.

FIG. 10 is a plan view illustrating a second embodiment where the groove is provided on the surface of the metal wiring board.

FIG. 11 is a plan view illustrating a third embodiment where the groove is provided on the surface of the metal wiring board.

FIG. 12 is a plan view illustrating a fourth embodiment where the groove is provided on the surface of the metal wiring board.

### DESCRIPTION OF EMBODIMENTS

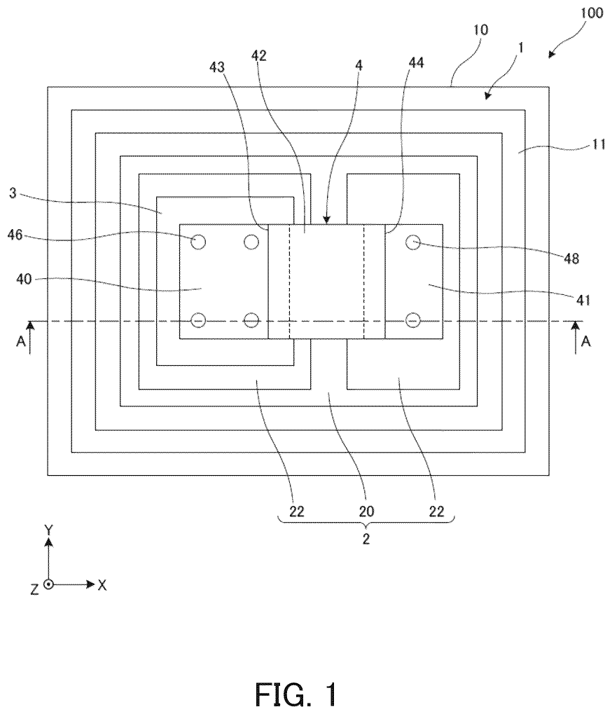

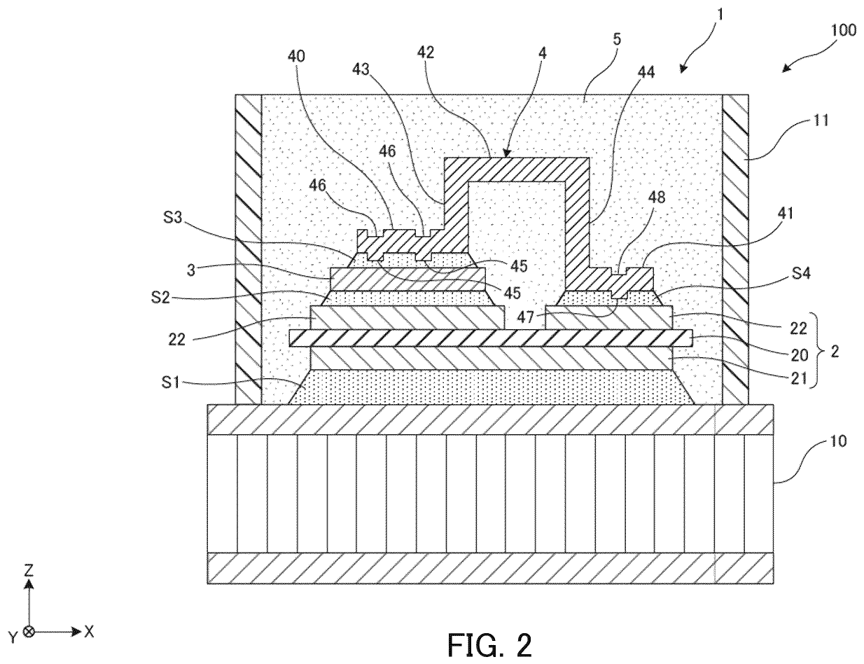

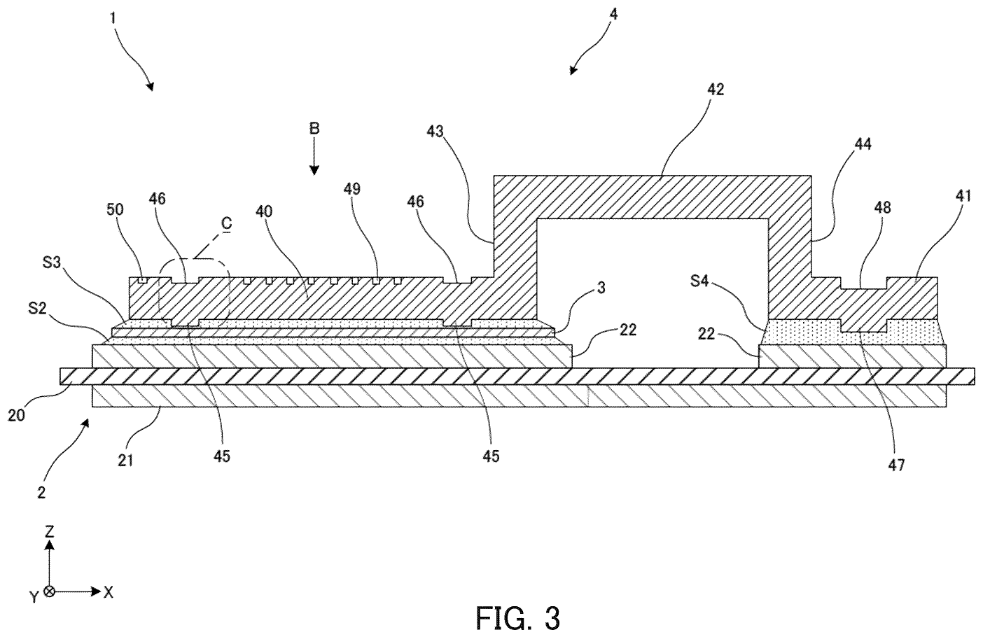

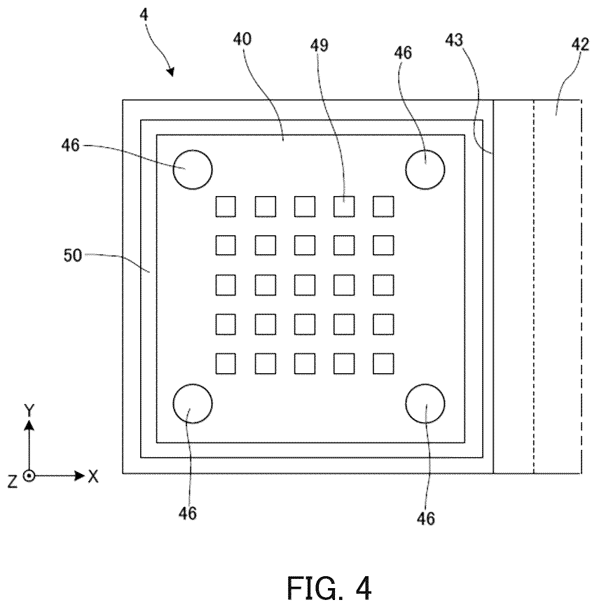

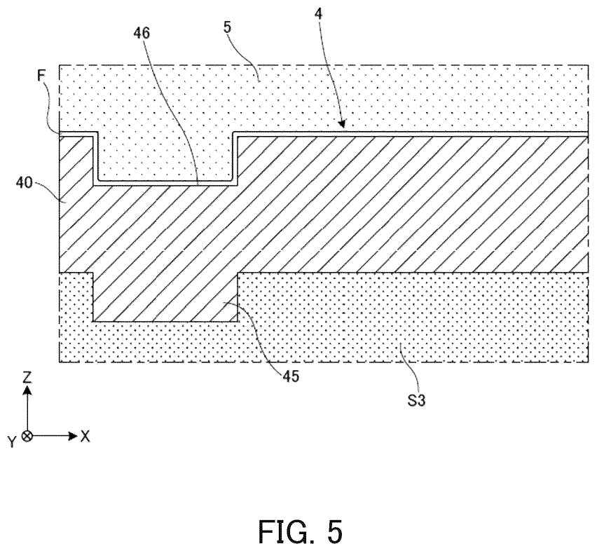

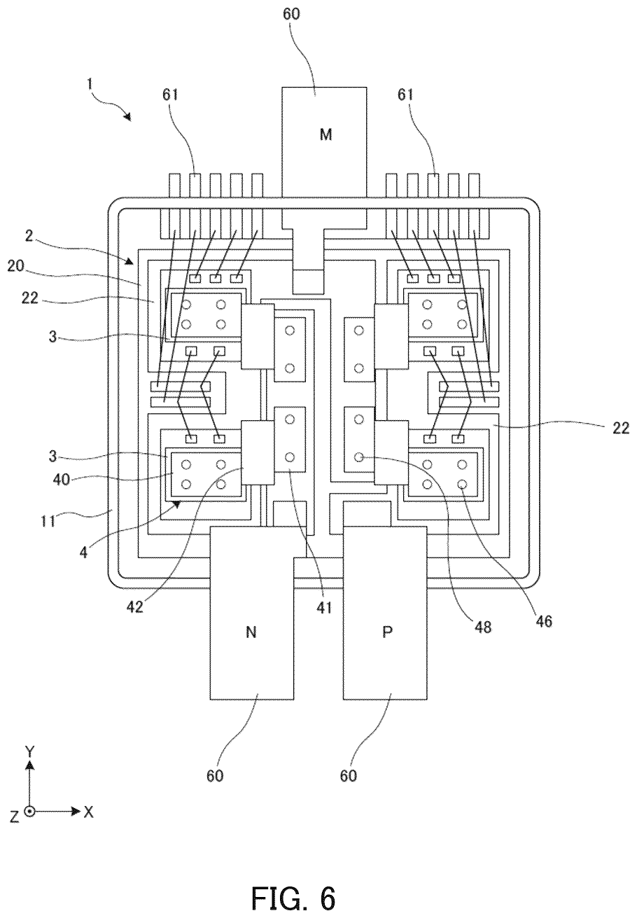

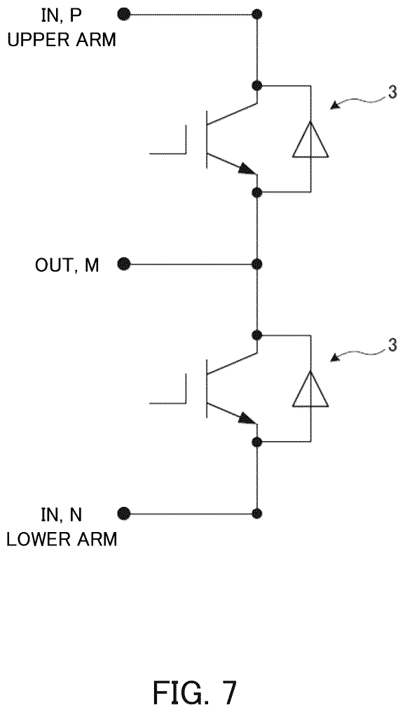

Hereinafter, a semiconductor module and a semiconductor device to which the present invention can be applied will be described. First, referring to FIGS. 1 to 7, the entirety of a semiconductor module and a semiconductor device and a schematic configuration of a metal wiring board including the semiconductor module and the semiconductor device will be described. FIG. 1 is a schematic view of a semiconductor device according to a present embodiment as viewed from above. FIG. 2 is a cross-sectional view of the semiconductor device illustrated in FIG. 1 taken along line A-A. FIG. 3 is an enlarged view of a metal wiring board according to the present embodiment. FIG. 4 is a plan view of the metal wiring board illustrated in FIG. 3 as viewed in a direction of arrow B. FIG. 5 is an enlarged view of a portion C of the metal wiring board illustrated in FIG. 3. FIG. 6 is a plan view illustrating a specific example of a semiconductor module to which the metal wiring board according to the present embodiment is applied. FIG. 7 is an equivalent circuit diagram of the semiconductor device according to the present embodiment. Here, the configuration is such that anti-parallel circuits of an IGBT and an FWD are connected in series as a semiconductor element 3.

In the following drawings, a longitudinal direction of the semiconductor module (a cooler) is defined as an X direction, a lateral direction of the semiconductor module (the cooler) is defined as a Y direction, and a height direction (a direction of the thickness of the substrate) is defined as a Z direction. The longitudinal direction of the semiconductor module indicates a direction in which the plurality of circuit boards are arrayed. X, Y, and Z axes illustrated are orthogonal to each other and form a right-handed system. In some cases, the X direction may be referred to as a left-right direction, the Y direction may be referred to as a front-rear direction, and the Z direction may be referred to as an up-down direction. These directions (front-rear, left-right, and up-down directions) are terms used for convenience of description, and a correspondence relationship with the XYZ directions, respectively, may change depending on an attachment posture of the semiconductor module. For example, a heat dissipation surface side (cooler side) of the semiconductor module is referred to as a lower surface side, and the opposite side is referred to as an upper surface side. Also, in the present specification, the term “in plan view” means a case where an upper surface or a lower surface of the semiconductor module is viewed in the Z direction. In addition, the ratio between the width and the thickness and the size relationship between the members in the drawings are illustrated in schematic views, and thus are not necessarily the same among the drawings. For convenience of description, it is also assumed that the size relationship between the members may be exaggerated.

A semiconductor device 100 according to the present embodiment is applied to, for example, a power conversion device such as an inverter of an industrial or in-vehicle motor. As illustrated in FIGS. 1 and 2, the semiconductor device 100 is configured by arranging a semiconductor module 1 on an upper surface of a cooler 10. Note that the cooler 10 has any configuration with respect to the semiconductor module 1.

The cooler 10 releases heat of the semiconductor module 1 to the outside, and has a rectangular parallelepiped shape as a whole. Although not particularly illustrated, the cooler 10 is configured by providing a plurality of fins on a lower surface side of a base plate and housing these fins in a water jacket. Note that the cooler 10 is not limited thereto and can be appropriately changed.

The semiconductor module 1 is configured by arranging a stacked substrate 2, the semiconductor element 3, a metal wiring board 4, and the like in a case 11.

The stacked substrate 2 is composed of, for example, a direct copper bonding (DCB) substrate, an active metal brazing (AMB) substrate, or a metal base substrate. The stacked substrate 2 is configured by stacking an insulating plate 20, a heat dissipation plate 21, and a plurality of circuit boards 22, and is formed into a rectangular shape as a whole in plan view.

Specifically, the insulating plate 20 is formed from a plate-shaped body having an upper surface and a lower surface, and has a rectangular shape elongated in the X direction in plan view. The insulating plate 20 may be formed from, for example, a ceramic material such as aluminum oxide (Al₂O₃), aluminum nitride (AlN), silicon nitride (Si₃N₄), and aluminum oxide (Al₂O₃) and zirconium oxide (ZrO₂).

In addition, the insulating plate 20 may be formed from, for example, a thermosetting resin such as an epoxy resin or a polyimide resin, or a composite material using glass or a ceramic material as a filler in the thermosetting resin. The insulating plate 20 preferably has flexibility and may be formed from, for example, a material containing a thermosetting resin. Further, the insulating plate 20 may be referred to as an insulating layer or an insulating film.

The heat dissipation plate 21 has a predetermined thickness in the Z direction and has a rectangular shape elongated in the Y direction in plan view. The heat dissipation plate 21 is formed from, for example, a metal plate having good thermal conductivity such as copper or aluminum. The heat dissipation plate 21 is arranged on a lower surface of the insulating plate 20. The lower surface of the heat dissipation plate 21 is a surface to be attached to the cooler 10, a device to which the semiconductor module 1 is attached, and also functions as a heat dissipation surface (heat dissipation region) for releasing heat of the semiconductor module 1. The heat dissipation plate 21 is bonded to the upper surface of the cooler 10 via a bonding material S1 such as solder. The heat dissipation plate 21 may be arranged on the upper surface of the cooler 10 with a thermal conductive material, such as thermal grease or thermal compound, interposed therebetween.

Each of the plurality of circuit boards 22 has a predetermined thickness and is arranged on the upper surface of the insulating plate 20. Each of the circuit boards 22 is formed into an electrically independent island shape. For example, the circuit board 22 has a rectangular shape in plan view, and is arranged side by side in the X direction on the insulating plate 20. Note that the number of the circuit boards 22 is not limited to two as illustrated in FIG. 1, and can be changed as appropriate. As illustrated in FIG. 6, three or more circuit boards 22 may be arranged on the insulating plate 20. In addition, the shape, arrangement location, and the like of the circuit board 22 are not limited thereto and can be changed as appropriate. These circuit boards 22 are formed from, for example, a metal plate having good thermal conductivity such as copper or aluminum. The circuit board 22 may be referred to as a circuit layer or a circuit pattern.

The semiconductor element 3 is arranged on an upper surface of the predetermined circuit board 22 (circuit board 22 on the negative side in the X direction) via a bonding material S2 such as solder. The semiconductor element 3 is formed from a semiconductor substrate such as silicon (Si) or silicon carbide (SiC) in a rectangular shape in plan view. The semiconductor element 3 may be a power semiconductor element. For the semiconductor element 3, a switching element such as an insulated gate bipolar transistor (IGBT) and a power metal oxide semiconductor field effect transistor (power MOSFET), and a diode such as a free wheeling diode (FWD) are used.

In the present embodiment, the semiconductor element 3 includes, for example, a reverse conducting (RC)-insulated gate bipolar transistor (IGBT) element in which the functions of an IGBT element and a free wheeling diode (FWD) element are integrated.

Note that the semiconductor element 3 is not limited thereto, and may be configured by combining the above-described switching element, diode, and the like. For example, the IGBT element and the FWD element may be configured separately. Also, a reverse blocking (RB)-IGBT or the like having a sufficient withstand voltage against a reverse bias may be used as the semiconductor element 3. In addition, the shape, number, arrangement location, and the like of the semiconductor element 3 can appropriately be changed.

In addition, electrodes (not illustrated) are formed on an upper surface and a lower surface of the semiconductor element 3, respectively. For example, the electrode on the upper surface side (upper surface electrode) is configured as an emitter electrode (source electrode) or a gate electrode, and the electrode on the lower surface side (lower surface electrode) is configured as a collector electrode (drain electrode).

Note that the semiconductor element 3 in the present embodiment is a so-called vertical switching element in which the functional element as described above is formed on a semiconductor substrate, but is not limited thereto, and may be a horizontal switching element.

The metal wiring board 4 is arranged on the upper surface of the semiconductor element 3. The metal wiring board 4 is configured as a plate-shaped body having an upper surface and a lower surface, and is formed from, for example, a metal material such as a copper material, a copper alloy-based material, an aluminum alloy-based material, or an iron alloy-based material. The metal wiring board 4 is formed into a predetermined shape by, for example, pressing. Note that the shape of the metal wiring board 4 described below is merely an example, and can be changed as appropriate. In addition, the metal wiring board may be referred to as a lead frame.

The metal wiring board 4 according to the present embodiment is an elongated body extending in the X direction so as to straddle the plurality of circuit boards 22 in plan view, and has a crank shape that is bent a plurality of times in side view. Specifically, as illustrated in FIGS. 2 and 3, the metal wiring board 4 is configured by including a first bonding portion 40 bonded to the upper surface (the upper surface electrode) of the semiconductor element 3 via a bonding material S3 (a first bonding material), a second bonding portion 41 bonded to the upper surface of the circuit board 22 on the positive side in the X direction via a bonding material S4, and a connecting portion 42 connecting the first bonding portion 40 and the second bonding portion 41.

The width of the metal wiring board 4 in the Y direction is uniform from the first bonding portion 40 to the second bonding portion 41. In addition, the first bonding portion 40, the second bonding portion 41, and the connecting portion 42 are arranged in a line along the X direction in plan view. Note that the width of the metal wiring board 4 in the Y direction is not necessarily uniform from the first bonding portion 40 to the second bonding portion 41, and each portion may have a different width as illustrated in FIG. 6. In addition, the first bonding portion 40, the second bonding portion 41, and the connecting portion 42 are not necessarily arranged in a line, and may be arranged to be obliquely shifted from each other as illustrated in FIG. 6.

The first bonding portion 40 is formed into a rectangular shape smaller than the outer shape of the semiconductor element 3 in plan view, and includes a plate-shaped portion having an upper surface and a lower surface. A first bent portion 43 that is bent at a substantially right angle and rises upward is formed at an end portion of the first bonding portion 40 on the positive side in the X direction (the connecting portion 42 side). One end (the left end) of the connecting portion 42 is connected to the upper end of the first bent portion 43. Although details will be described later, a plurality of bosses 45 protruding toward the semiconductor element 3 are formed on a lower surface of the first bonding portion 40. In addition, on the upper surface of the first bonding portion 40, a bottomed hole 46 is formed at a location corresponding to a position immediately above the boss 45.

The second bonding portion 41 is formed into a rectangular shape smaller than the outer shape of the circuit board 22 in plan view, and includes a plate-shaped portion having an upper surface and a lower surface. A second bent portion 44 that is bent at a substantially right angle and rises upward is formed at an end portion of the second bonding portion 41 on the negative side in the X direction (the connecting portion 42 side). The other end (the right end) of the connecting portion 42 is connected to the upper end of the second bent portion 44. Although details will be described later, a plurality of bosses 47 protruding toward the circuit board 22 are formed on a lower surface of the second bonding portion 41. In addition, on the upper surface of the second bonding portion 41, a bottomed hole 48 is formed at a location corresponding to a position immediately above the boss 47.

The connecting portion 42 extends in the horizontal direction, and as described above, one end thereof is connected to the first bent portion 43 and the other end thereof is connected to the second bent portion 44.

The length of the first bent portion 43 in the Z direction is shorter than that of the second bent portion 44 by the thickness of the semiconductor element 3. That is, the first bonding portion 40 and the second bonding portion 41 are provided at a position with different heights. More specifically, the first bonding portion 40 is provided at a position higher than the second bonding portion 41.

Note that the shape, number, arrangement location, and the like of the metal wiring board 4 described above are merely examples, and are not limited thereto and can be changed as appropriate. Although details will be described later, a plurality of (for example, four) metal wiring boards 4 may be arranged on one semiconductor module as illustrated in FIG. 6. Also, in the present embodiment, the semiconductor element 3 and the metal wiring board 4 described above, and a main terminal and the like to be described later form, for example, an inverter circuit illustrated in FIG. 7.

The periphery of the stacked substrate 2, the semiconductor element 3, and the metal wiring board 4 is surrounded by the case 11. The case 11 has a quadrangular annular tubular shape or a frame shape in plan view, and is formed from, for example, a synthetic resin. The case 11 may be formed from, for example, a thermosetting resin material such as an epoxy resin or silicone rubber. The lower end of the case 11 is adhered to the upper surface of the cooler 10 with an adhesive (not illustrated), and the upper end extends to a position sufficiently higher than the upper surface of the metal wiring board 4. Thus, the case 11 surrounds the periphery of the stacked substrate 2, the semiconductor element 3, and the metal wiring board 4, and defines a space for housing the stacked substrate 2, the semiconductor element 3, and the metal wiring board 4.

The internal space defined by the case 11 is filled with a sealing resin 5. The case 11 may be filled with the sealing resin 5 until its upper surface reaches the upper end of the case 11. Thus, the stacked substrate 2, the semiconductor element 3, and the metal wiring board 4 are sealed. The entire metal wiring board 4 is covered with the sealing resin 5.

The sealing resin 5 may be composed of, for example, a thermosetting resin. Preferably, the sealing resin 5 contains at least one of epoxy, silicone, urethane, polyimide, polyamide, and polyamide-imide. For example, an epoxy resin mixed with a filler is suitable for the sealing resin 5 from the viewpoint of insulation, heat resistance, and heat dissipation properties.

As in the specific example illustrated in FIG. 6, the case 11 may be provided with a plurality of main terminals 60 for main current and a plurality of control terminals 61 for control. The main terminal 60 is formed into a plate-shaped elongated body and is embedded in a side wall of the case 11. In FIG. 6, two main terminals 60 constituting an N terminal and a P terminal, respectively, are arranged side by side in the X direction on the side wall of the case 11 positioned on the negative side in the Y direction. In addition, a main terminal 60 constituting an M terminal is arranged on the side wall of the case 11 positioned on the positive side in the Y direction.

As described above, in the present embodiment, the semiconductor element 3, the metal wiring board 4, the main terminals 60, and the like form, for example, the inverter circuit illustrated in FIG. 7. These main terminals 60 (the N terminal, P terminal, M terminal) correspond to IN (N) (which may be referred to as a low potential-side input terminal or a negative electrode terminal), IN (P) (which may be referred to as a high potential-side input terminal or a positive electrode terminal), and OUT (M) (which may be referred to as an output terminal or an intermediate terminal) in FIG. 7, respectively.

In addition, the control terminal 61 is formed into a plate-shaped elongated body and is embedded in the side wall of the case 11 positioned on the positive side in the Y direction. The control terminal 61 is electrically connected to a predetermined control electrode of the semiconductor element 3 via a wiring member such as a bonding wire. These main terminal 60 and the control terminal 61 are formed from a metal material such as a copper material, a copper alloy-based material, an aluminum alloy-based material, or an iron alloy-based material, and have predetermined electrical conductivity and predetermined mechanical strength. The shapes, numbers, arrangement locations, and the like of the main terminal 60 and the control terminal 61 are not limited thereto, and can be changed as appropriate.

Incidentally, in the semiconductor module, it is desired to prevent the progress of peeling along the interface between the metal wiring board and the sealing resin. As a method for reducing peeling, it is conceivable, for example, to increase the surface area of the metal wiring board to improve adhesion (anchor effect) between the metal wiring board and the sealing resin. Examples of a method for increasing the surface area of the metal wiring board include forming an uneven shape on the surface of the metal wiring board. However, when the lower surface of the metal wiring board (the surface facing the semiconductor element) has an uneven shape, voids and sink marks are likely to occur in the bonding material. As a result, the mounting quality of the metal wiring board may be affected.

Also, examples of a method for roughening the surface of the metal wiring board include laser processing and a wet method using a chemical solution. However, these methods not only cause an increase in cost, but also may cause voids and sink marks in the bonding material due to a roughened lower surface side of the metal wiring board. That is, it is difficult to roughen the surface of the metal wiring board without affecting the quality of the bonding material immediately below the metal wiring board.

In the present embodiment, the bottomed hole 46 is formed by recessing the first bonding portion 40 of the metal wiring board 4 from the upper surface side, and the boss 45 protruding from the lower surface side is provided on the back side of the bottomed hole 46. In addition, a plurality of roughened recessed portions 49 smaller than the bottomed hole 46 are formed on the upper surface of the first bonding portion 40 thereby to form a roughened region.

The boss 45 is arranged at each of positions close to the four corners of the rectangular first bonding portion 40 in plan view. By forming the plurality of bosses 45 in this manner, the first bonding portion 40 is not inclined with respect to the upper surface of semiconductor element 3 in a bonding step of the metal wiring board 4. Thus, the posture of the metal wiring board 4 (the first bonding portion 40) can be stabilized.

In particular, by providing the boss 45 on the lower surface of the metal wiring board 4, a gap can be secured between the first bonding portion 40 and the semiconductor element 3 by at least the height of the boss 45. By filling the gap with the bonding material S3, the thickness of the bonding material S3 can be secured.

In addition, the upper surface of the first bonding portion 40 in the roughened region is roughened by forming the plurality of roughened recessed portions 49. As a result, the surface area of the upper surface of the first bonding portion 40 increases, and the adhesion (anchor effect) between the upper surface of the first bonding portion 40 and the sealing resin 5 can be improved. In particular, it is preferable that the sealing resin 5 enters the roughened recessed portions 49. As a result, a further anchor effect can be expected. Accordingly, the progress of the peeling of the sealing resin 5 on the upper surface of the metal wiring board 4 due to thermal stress can be suppressed at a position above the semiconductor element 3.

In addition, the bottomed hole 48 is formed by recessing the second bonding portion 41 from the upper surface side, and the boss 47 protruding from the lower surface side is provided on the back side of the bottomed hole 48. As a result, a gap can be secured between the second bonding portion 41 and the circuit board 22 by at least the height of the boss 47. By filling the gap with the bonding material S4, the thickness of the bonding material S4 can be secured.

The bosses 45, the bottomed holes 46, and the roughened recessed portions 49 in the first bonding portion 40 and the bosses 47, the bottomed holes 48 in the second bonding portion 41 are formed, for example, by pressing.

Note that the plurality of roughened recessed portions 49 may be formed on the upper surface of the second bonding portion 41, or may be formed only on the upper surface of the first bonding portion 40. That is, the roughened recessed portions 49 do not need to be formed in the connecting portion 42, the first bent portion 43, and the second bent portion 44 that constitute the portion other than the first bonding portion 40.

Since the semiconductor element 3 serving as a heat source is arranged immediately below the first bonding portion 40, it is possible to easily receive the influence of the anchor effect due to surface roughening. In addition, by roughening only the surface of the portion where the anchor effect is to be improved, it is not necessary to spend extra processing cost. That is, it can be said that the second bonding portion 41, the connecting portion 42, the first bent portion 43, and the second bent portion 44 have a smaller influence on the peeling of the sealing resin 5 than the first bonding portion 40. In this case, the surfaces of the second bonding portion 41, the connecting portion 42, the first bent portion 43, and the second bent portion 44 are flat, and the surface roughness thereof may be equivalent to the surface roughness of the lower surface of the first bonding portion 40.

In addition, the portion of the lower surface of the first bonding portion 40 excluding the boss 45 is preferably a flat surface. That is, it is preferable that the roughened recessed portions 49 are not formed on the lower surface of the first bonding portion 40. For example, the surface roughness of the lower surface of the first bonding portion 40 is preferably smaller than the surface roughness of the upper surface of the first bonding portion 40. When the lower surface of the first bonding portion 40 is flat, voids and sink marks are unlikely to be generated in the bonding material S3.

In addition, as illustrated in FIG. 5, a coating film F may be interposed at the interface between the upper surface of the first bonding portion 40 and the sealing resin 5.

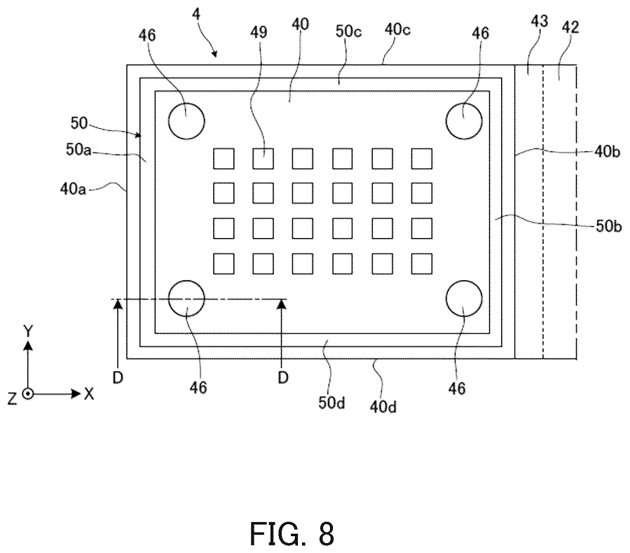

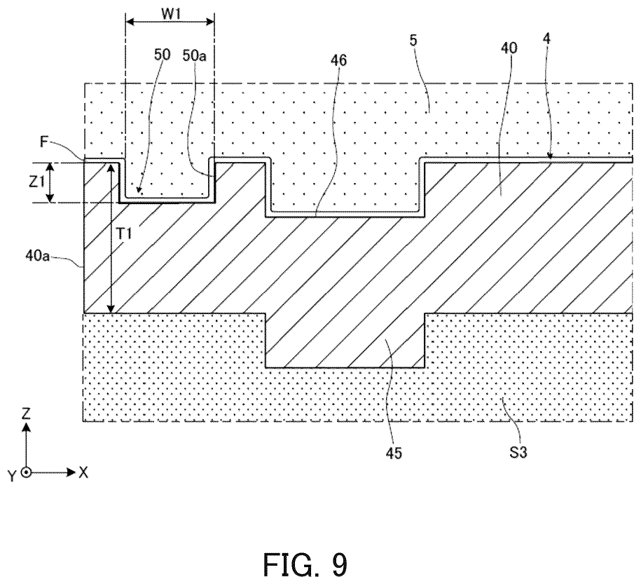

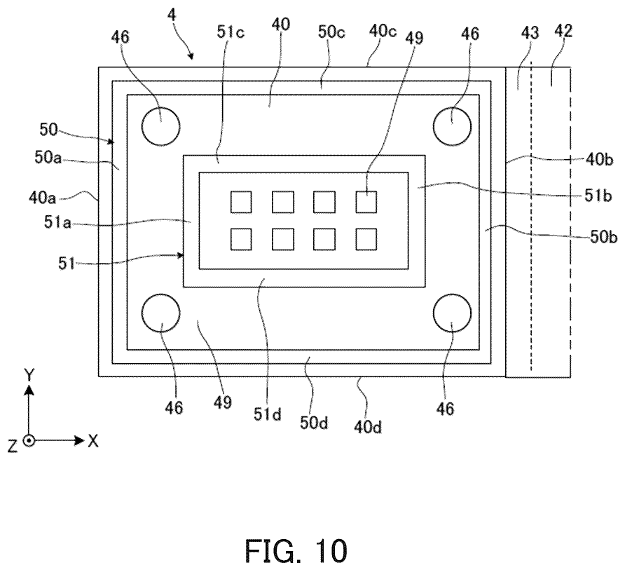

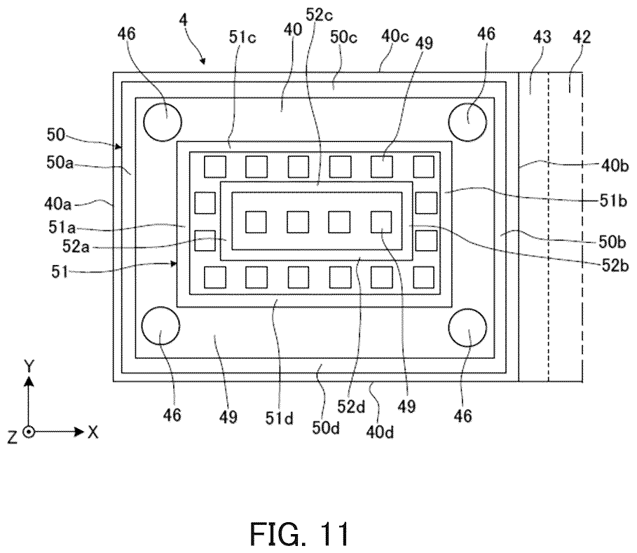

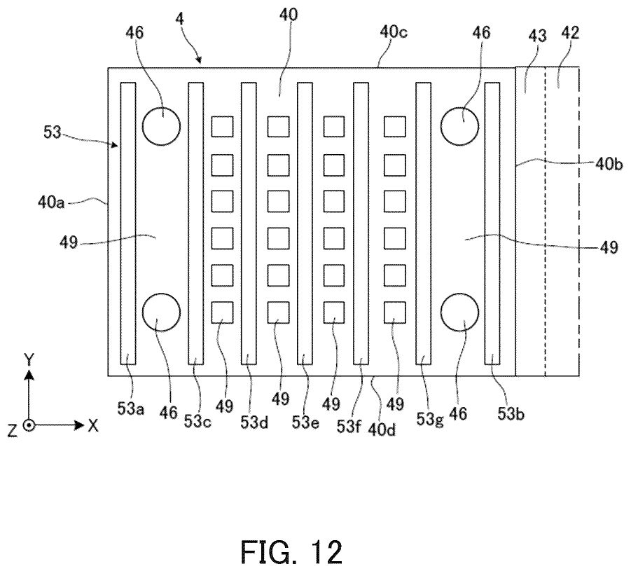

Next, referring to FIGS. 8 to 12, embodiments where a groove is provided on the upper surface of the first bonding portion 40 will be described. FIGS. 8 and 9 illustrate a first embodiment, FIG. 10 illustrates a second embodiment, FIG. 11 illustrates a third embodiment, and FIG. 12 illustrates a fourth embodiment. The upper surface of the first bonding portion 40 according to each of the embodiments includes a roughened region that is roughened by the plurality of roughened recessed portions 49 and a non-roughened region where the roughened recessed portions 49 is not formed. The non-roughened region includes four bottomed holes 46.

In all of the first embodiment to the fourth embodiment, at least one groove is provided along the outer periphery of the first bonding portion 40 on the upper surface of the first bonding portion 40. “Along the outer periphery” represents that the groove extends substantially in the same direction as that of the outer edge of the first bonding portion 40 at positions near the outer edge of the first bonding portion 40. In addition, “groove” refers to a member having a belt-like shape that is longer than at least the roughened recessed portion 49.

In the first embodiment illustrated in FIGS. 8 and 9, a groove 50 having a rectangular frame shape is provided in the upper surface of the first bonding portion 40. The groove 50 is arranged to surround the outer side of all the bottomed holes 46 and all the roughened recessed portions 49.

Specifically, the first bonding portion 40 having a rectangular shape in plan view includes a tip outer edge 40a on a tip side in the X direction (end portion opposite to the connecting portion 42) and includes a boundary portion 40b that is a boundary between the first bent portion 43 and an end portion opposite to the tip outer edge 40a in the X direction. Each of the tip outer edge 40a and the boundary portion 40b has a linear shape extending in the Y direction. In addition, the first bonding portion 40 includes a pair of lateral outer edges 40c and 40d that connect opposite ends of the tip outer edge 40a and the boundary portion 40b extending in the X direction.

The groove 50 includes a pair of linear portions 50a and 50b extending in the Y direction along the tip outer edge 40a and the boundary portion 40b and a pair of linear portions 50c and 50d extending in the X direction along the pair of lateral outer edges 40c and 40d. A predetermined interval is present in the X direction at each of a position between the tip outer edge 40a and the linear portion 50a and a position between the boundary portion 40b and the linear portion 50b. A predetermined interval is present in the Y direction at each of a position between the lateral outer edge 40c and the linear portion 50c and a position between the lateral outer edge 40d and the linear portion 50d. On the outer peripheral side further than the groove 50, the upper surface of the first bonding portion 40 has a flat shape.

FIG. 9 illustrates a cross-sectional structure of the first bonding portion 40 at a position taken along line D-D of FIG. 8. The upper surface of the first bonding portion 40 is covered with the sealing resin 5, and a coating film F is interposed at the interface between the upper surface of the first bonding portion 40 and the sealing resin 5. The peeling at the interface between the first bonding portion 40 and the sealing resin 5 is likely to occur from the outer peripheral portion of the first bonding portion 40, and the peeling occurring in the outer peripheral portion of the first bonding portion 40 progresses toward the inner region of the first bonding portion 40.

Due to the structure of the metal wiring board 4, thermal deformation (expansion, shrinkage) occurs with respect to the axis that is a rising portion such as the first bent portion 43 or the second bent portion 44 in the connecting portion 42. Therefore, when the thermal deformation occurs, the amount of displacement on the tip side where the tip outer edge 40a is positioned in the first bonding portion 40 increases. Thus, in the first bonding portion 40, the peeling in the X direction tends to progress from the tip outer edge 40a toward the connecting portion 42. In particular, at a cross-sectional position illustrated in FIG. 9, the non-roughened region where the roughened recessed portion 49 is not provided is connected to an extended line from the tip outer edge 40a in the X direction, and a condition where the peeling is likely to progress toward the inside of the first bonding portion 40 is satisfied.

Here, by providing the groove 50, in the region along the outer periphery of the first bonding portion 40 that is likely to be the origin of peeling, the surface area of the first bonding portion 40 increases, and the adhesion (anchor effect) between the upper surface of the first bonding portion 40 and the sealing resin 5 can be improved. As a difference from the plurality of roughened recessed portions 49 that are arranged at intervals in the X direction or the Y direction on the upper surface of the first bonding portion 40, the groove 50 has a shape that is continuous in the X direction or the Y direction. Therefore, in any portion along the outer periphery of the first bonding portion 40, the groove 50 is present and can prevent a smooth surface from being continuous from the outer peripheral side to the inner peripheral side of the first bonding portion 40.

For example, when peeling that progresses in the X direction from the tip outer edge 40a of the first bonding portion 40 is assumed, the linear portion 50a of the groove 50 extends in a direction (Y direction) orthogonal to the progress direction (X direction) of the peeling. With this configuration, the linear portion 50a of the groove 50 can suppress the progress of peeling in the X direction. Further, in the roughened region where the roughened recessed portions 49 are provided inside the groove 50, the anchor effect by the roughened recessed portions 49 can also be obtained. Even in the non-roughened region such as the cross-sectional position illustrated in FIG. 9, the linear portion 50a of the groove 50 is continuously formed along the tip outer edge 40a of the first bonding portion 40. Therefore, the progress of peeling in the X direction from the tip outer edge 40a can be suppressed by the groove 50.

FIG. 9 illustrates the linear portion 50a of the groove 50 along the tip outer edge 40a. However, not only in the linear portion 50a but also in the other linear portions 50b, 50c, and 50d, the effect of suppressing the progress of peeling of the sealing resin 5 from the outer peripheral side of the first bonding portion 40 is obtained. For example, the progress of peeling in the Y direction from the lateral outer edges 40c and 40d can be suppressed by the linear portions 50c and 50d. In addition, the progress of peeling in the X direction from the boundary portion 40b with the first bent portion 43 can be suppressed by the linear portion 50b.

As illustrated in FIG. 9, the groove 50 is a bottomed groove having a square U-shape (rectangular shape) in cross-section that is opened to the upper surface of the first bonding portion 40. From the viewpoint of securing the strength of the metal wiring board 4 to prevent deformation, a depth Z1 of the groove 50 is preferably 30% or less of a thickness T1 of the first bonding portion 40. In addition, an open width W1 of the groove 50 is preferably 50 μm or more and 600 μm or less.

In order to stabilize the posture of the metal wiring board 4, the boss 45 is provided at positions close to four corners of the lower surface of the first bonding portion 40, and the bottomed hole 46 (non-roughened region) formed at the location corresponding to the position immediately above the boss 45 is arranged at positions close to four corners of the upper surface of the first bonding portion 40. Even in the vicinity of the four corners of the first bonding portion 40 that is difficult to be roughened by the roughened recessed portions 49, by arranging one or more arrays of the groove 50 on the outer peripheral side further than the bottomed hole 46 that is the non-roughened region, the progress of the peeling up to the position of the bottomed hole 46 can be suppressed by the groove 50.

The cross-sectional shape of the groove 50 may be a shape other than the square U-shape. For example, the groove 50 can also be configured in a cross-sectional shape such as a U-shape or a semi-circular shape.

In the second embodiment illustrated in FIG. 10, in addition to the groove 50 along the outer periphery of the first bonding portion 40, a second groove 51 is provided as another groove positioned inside of the groove 50 on the upper surface of the first bonding portion 40. The second groove 51 is a groove having a rectangular frame shape as in the groove 50 and includes a pair of linear portions 51a and 51b extending in the Y direction and a pair of linear portions 51c and 51d extending in the X direction. A plurality (four) of bottomed holes 46 are arranged between the groove 50 and the second groove 51. The inside of the second groove 51 is the roughened region where the plurality of roughened recessed portions 49 are arranged.

As in the roughened recessed portions 49 or the groove 50, the second groove 51 has the effect of increasing the surface area of the first bonding portion 40 to improve the adhesion between the upper surface of the first bonding portion 40 and the sealing resin 5. Even if the peeling of the sealing resin 5 progresses up to the inside of the location of the groove 50 in the first bonding portion 40, the progress of peeling can be suppressed by the second groove 51. Since the second groove 51 is continuous in a frame shape, even in a range where the roughened recessed portions 49 are not present in the X direction and the Y direction, the effect of reliably suppressing the progress of peeling by the second groove 51 can be obtained.

In the third embodiment illustrated in FIG. 11, in addition to the groove 50 and the second groove 51, a third groove 52 is provided as another groove positioned further inside of the second groove 51 on the upper surface of the first bonding portion 40. The third groove 52 is a groove having a rectangular frame shape as in the groove 50 or the second groove 51 and includes a pair of linear portions 52a and 52b extending in the Y direction and a pair of linear portions 52c and 52d extending in the X direction. A region between the second groove 51 and the third groove 52 is the roughened region where the plurality of roughened recessed portions 49 are arranged. Further, the inside of the third groove 52 is also the roughened region where the plurality of roughened recessed portions 49 are arranged.

As in the roughened recessed portions 49, the groove 50, or the second groove 51, the third groove 52 has the effect of increasing the surface area of the first bonding portion 40 to improve the adhesion between the upper surface of the first bonding portion 40 and the sealing resin 5. Even if the peeling of the sealing resin 5 progresses up to the inside of the location of the groove 50 or the second groove 51 in the upper surface of the first bonding portion 40, the progress of peeling can be suppressed by the third groove 52. Since the third groove 52 is continuous in a frame shape, even in a range where the roughened recessed portions 49 are not present in the X direction and the Y direction, the effect of reliably suppressing the progress of peeling by the third groove 52 can be obtained.

The groove formed on the upper surface of the first bonding portion 40 is not limited to the frame shape as in the groove 50, the second groove 51, and the third groove 52. The fourth embodiment illustrated in FIG. 12 is a configuration example where a plurality of parallel grooves 53 (53a to 53g) are formed on the upper surface of the first bonding portion 40. The respective grooves 53a to 53g linearly extend in the Y direction and are arranged at predetermined intervals in the X direction. All of the grooves 53a to 53g are formed to be longer than the distance between two bottomed holes 46 in the Y direction.

Among the plurality of grooves 53, the groove 53a arranged closest to the tip side in the first bonding portion 40 is positioned between the tip outer edge 40a and the bottomed holes 46 (two bottomed holes 46 at positions close to the tip outer edge 40a). The groove 53b arranged at a position closest to the first bent portion 43 is positioned between the boundary portion 40b and the bottomed holes 46 (two bottomed holes 46 at positions close to the boundary portion 40b). That is, the two grooves 53a and 53b are formed on the outer peripheral side in the X direction further than each of the bottomed holes 46. Further, the grooves 53c, 53d, 53e, 53f, and 53g are formed between the groove 53a and the groove 53b as other grooves positioned inside of the grooves 53a and 53b on the upper surface of the first bonding portion 40. Each of regions between the grooves 53c to 53g is the roughened region where the plurality of roughened recessed portions 49 are formed.

As described above, in the first bonding portion 40, the peeling of the sealing resin 5 is likely to progress in the X direction from the tip side where the tip outer edge 40a is present. By providing the grooves 53a to 53g extending in the Y direction orthogonal to the X direction in which peeling progresses, the effect of suppressing the peeling of the sealing resin 5 can be improved. In particular, since the groove 53a is arranged on the tip side opposite to the connecting portion 42, the progress of peeling can be effectively suppressed at an initial stage. In addition, since the groove 53a is formed on the outer peripheral side (between the tip outer edge 40a and the bottomed hole 46) further than the bottomed hole 46, the progress of peeling up to the bottomed hole 46 can be prevented by the groove 53a.

The groove 50, the second groove 51, the third groove 52, and the plurality of grooves 53 illustrated in FIGS. 8 to 12 can be formed, for example, by pressing or cutting.

In the above-described embodiment, the first bonding portion 40 of the metal wiring board 4 includes the bottomed holes 46 in the non-roughened region of the upper surface. However, the configuration of the non-roughened region is not limited to the bottomed holes. For example, when a wire is connected to the upper surface of the metal wiring board 4, a location to which the wire is to be connected may be the non-roughened region. In addition, a protrusion portion that protrudes upward from the metal wiring board 4, a through hole or the like that penetrates the upper surface and the lower surface of the metal wiring board 4, or the like can also be applied as the non-roughened region. In either case, by arranging one or more arrays of the grooves on the outer peripheral side further than the non-roughened region, the above-described effect can be obtained.

In addition, the present invention is also applicable to the first bonding portion of the metal wiring board that does not include the non-roughened region such as the bottomed holes 46 on the upper surface. In addition, the present invention is also applicable to the first bonding portion of the metal wiring board having the upper surface that is not roughened by the roughened recessed portions 49 (that does not include the roughened recessed portions 49).

As described above, with the present embodiment, the adhesion between the metal wiring board and the sealing resin can be improved. In addition, according to the present invention, it is possible to improve the bonding strength between the semiconductor element and the metal wiring board while securing the thickness of the bonding material.

Although the present embodiment and the modification examples have been described above, the above-described embodiment and modification examples may be wholly or partially combined as another embodiment.

In the above-described embodiment, the number and arrangement location of the semiconductor element are not limited to the above-described configuration, and can appropriately be changed.

Furthermore, in the above-described embodiment, the number and layout of the circuit board are not limited to the above-described configuration, and can be changed as appropriate.

In the above-described embodiment, the stacked substrate or the semiconductor element has a rectangular shape or a square shape in a planar view, but the present invention is not limited to this configuration. These components may each have a polygonal shape other than the above-described shape.

In addition, the present embodiment is not limited to the above-described embodiment and modification examples, and various changes, substitutions, and modifications may be made without departing from the spirit of the technical idea. Further, when the technical idea can be realized in another manner by the progress of the technology or another derived technology, the technical idea may be carried out by using a method thereof. Accordingly, the claims cover all implementations that may be included within the scope of the technical idea.

Feature points in the embodiment described above will be summarized below.

The semiconductor module according to the above-described embodiment includes: a stacked substrate in which a plurality of circuit boards are arranged on an upper surface of an insulating plate; a semiconductor element arranged on an upper surface of at least one of the circuit boards; and a metal wiring board arranged on an upper surface of the semiconductor element, in which the metal wiring board has a first bonding portion bonded to the upper surface of the semiconductor element via a bonding material, the first bonding portion includes a plate-shaped portion having an upper surface and a lower surface, and at least one groove is provided along an outer periphery of the first bonding portion on the upper surface of the plate-shaped portion.

In addition, a plurality of roughened recessed portions that are positioned inside of the groove and roughen the upper surface are provided on the upper surface of the plate-shaped portion.

In addition, a non-roughened region not including the roughened recessed portions is provided on the upper surface of the plate-shaped portion, and one or more arrays of the grooves are arranged on an outer peripheral side further than the non-roughened region.

In addition, another groove is positioned inside of the groove on the upper surface of the first bonding portion.

In addition, the metal wiring board includes a second bonding portion bonded to an upper surface of another one of the circuit boards via a bonding material and a connecting portion connecting the first bonding portion and the second bonding portion, and the groove is arranged at least along a tip side of the first bonding portion opposite to the connecting portion.

### INDUSTRIAL APPLICABILITY

As described above, the present invention has an effect of improving the adhesion between the bonding portion of the metal wiring board and the sealing resin and is particularly useful for a semiconductor module for industrial or electrical equipment.

The present application is based on Japanese Patent Application No. 2022-177076 filed on Nov. 4, 2022. All the contents are included herein.

### REFERENCE SIGNS LIST

1 Semiconductor module
2 Stacked substrate
3 Semiconductor element
4 Metal wiring board
5 Sealing resin
10 Cooler
11 Case
20 Insulating plate
21 Heat dissipation plate
22 Circuit board
40 First bonding portion
41 Second bonding portion
42 Connecting portion
43 First bent portion
44 Second bent portion
45 Boss
46 Bottomed hole (non-roughened region)
47 Boss
48 Bottomed hole
49 Roughened recessed portion
50 Groove
51 Second groove
52 Third groove
53 Groove
60 Main terminal
61 Control terminal
100 Semiconductor device
F Coating film
S1 Bonding material
S2 Bonding material
S3 Bonding material
S4 Bonding material
Z1 Depth of groove
W1 Open width of groove

1. A semiconductor module, comprising:
a stacked substrate including an insulating plate and a plurality of circuit boards arranged on an upper surface of the insulating plate;
a semiconductor element arranged on an upper surface of one of the plurality of circuit boards; and
a metal wiring board arranged on an upper surface of the semiconductor element, wherein
the metal wiring board has a first bonding portion bonded to the upper surface of the semiconductor element via a bonding material,
the first bonding portion has a plate-shaped portion having an upper surface and a lower surface opposite to each other, and
the plate-shaped portion has on the upper surface thereof, at least one groove is arranged along an outer periphery of the plate-shaped portion.

2. The semiconductor module according to claim 1, wherein the plate-shaped portion further has on the upper surface thereof, a roughened region closer to a center of the plate-shape portion than is a position of the groove and has a plurality of recesses configured to roughen a surface of the roughened region.

3. The semiconductor module according to claim 2, wherein
the plate-shaped portion further has on the upper surface thereof, a non-roughened region excluding the roughened region, and
the groove is provided in plurality, the plurality of grooves forming one or more arrays and being arranged closer to the outer periphery of the plate-shape portion than is the non-roughened region.

4. The semiconductor module according to claim 1, wherein the plate-shape portion has on the upper surface thereof, another groove positioned closer to a center of the plate-shape portion than is a position of the groove.

5. The semiconductor module according to claim 1, wherein
the metal wiring board includes a second bonding portion bonded to an upper surface of another one of the circuit boards via a bonding material and a connecting portion connecting the first bonding portion to the second bonding portion, and
the groove is arranged at least along one end of the first bonding portion opposite to another end of the first bonding portion connected to the connecting portion.
